(19) United States
(12) Patent Application Publication
(10) Pub. No.: US 2025/0042145 A1
(43) Pub. Date: Feb. 6, 2025

(54) LAMINATING DEVICE AND LAMINATION METHOD

(71) Applicant: THE JAPAN STEEL WORKS, LTD., Shinagawa-ku, Tokyo (JP)

(72) Inventor: Takayuki YAMAMOTO, Shinagawa-ku, Tokyo (JP)

(21) Appl. No.: 18/717,341

(22) PCT Filed: Dec. 15, 2022
(86) PCT No.: PCT/JP2022/046259

§ 371 Date: Jun. 6, 2024

(30) Foreign Application Priority Data
Dec. 24, 2021 (JP) 2021-211343

(51) Int. Cl. B32B 37/10; B32B 37/00

(52) U.S. Cl. CPC B32B 37/10; B32B 37/0046

(57) ABSTRACT

In a laminating device (3) that pressurizes a laminate (A4) including a substrate layer (A1) and a resin layer (A2) between opposing boards (312, 314) at a predetermined temperature, in at least one of the boards (312) and (314), a buffer (327) is provided between a plate-form member (328) forming a pressurizing surface (328a) and a pressurizing block body (323) or (324), and a peripheral part (327b) of the buffer (327) has a hardness higher than that in a central part (327a) of the buffer (327). Accordingly, it is possible to provide a laminating device and a lamination method capable of preventing resin in the vicinity of an end of the laminate from flowing out from a side surface of the laminate when the laminate including the substrate layer and the resin layer is pressurized in the laminating device.

### TECHNICAL FIELD

The present invention relates to a laminating device and a lamination method for pressurizing a laminate including a substrate layer and a resin layer between opposing boards of a press device at a predetermined temperature.

### BACKGROUND ART

One known laminate molding device which pressurizes a laminate including a substrate layer and a resin layer between opposing boards at a predetermined temperature is disclosed in Patent Literature 1. The laminate molding device disclosed in Patent Literature 1 includes heat boards that are opposed to each other and can come close to and move away from each other and pressurize a to-be-laminated material and a laminate material therebetween at a predetermined temperature. This laminate molding device further includes an elastically deformable mirror plate which is provided so as to be opposed to the heat boards with a buffer layer therebetween, the mirror plate pressurizing the to-be-laminated material or the laminate material.

### CITATION LIST

### Patent Literature

[Patent Literature 1] Japanese Unexamined Patent Application Publication No. 2002-120100

### SUMMARY OF INVENTION

However, in the laminate molding device disclosed in Patent Literature 1, the buffer layer is made of an uniform material, and thus when the to-be-laminated material and the laminate material (they are collectively referred to as a laminate hereafter) are pressurized by the mirror plate via the buffer, as shown in [FIG. 7] accompanied by the present specification, stress concentrates in the vicinity of an end of the laminate, which causes resin in the vicinity of the end to easily flow outside.

The present invention has been made to solve the aforementioned problem and one of objects of the present invention is to provide a laminating device and a lamination method capable of preventing, when a laminate including a substrate layer and a resin layer is pressurized using a laminating device in which a buffer is provided between a plate-form member forming a pressurizing surface and a pressurizing block body, resin in the vicinity of an end of the laminate from flowing out from a side surface of the laminate. The other problems of the related art and the novel characteristics of the present invention will be made apparent from the descriptions of the specification and the accompanying drawings.

A laminating device according to claim 1 of the present invention is a laminating device configured to pressurize a laminate including a substrate layer and a resin layer between opposing boards of a press device at a predetermined temperature, in which at least one of the boards includes a buffer between a plate-form member forming a pressurizing surface and a pressurizing block body, and a hardness of a peripheral part of the buffer is higher than that of a central part of the buffer.

The laminating device according to the present invention is a laminating device configured to pressurize a laminate including a substrate layer and a resin layer between opposing boards of a press device at a predetermined temperature, in which at least one of the boards includes a buffer between a plate-form member forming a pressurizing surface and a pressurizing block body, and a hardness of a peripheral part of the buffer is higher than that of a central part of the buffer, whereby it is possible to prevent resin in the vicinity of an end of the laminate from flowing outside from a side surface of the laminate when laminate-molding is performed. A lamination method according to the present invention also have similar effects.

### BRIEF DESCRIPTION OF DRAWINGS

FIG. 1 is a schematic explanatory view of a laminating device according to a first embodiment;

FIG. 2 is an enlarged cross-sectional view of a main part of a vacuum laminating device of the laminating device according to the first embodiment when pressure is applied;

FIG. 3 is an enlarged cross-sectional view of a main part of a press device of the laminating device according to the first embodiment when the pressure is applied;

FIG. 4 is an explanatory view showing a relation between a buffer of the press device of the laminating device and a laminate according to the first embodiment;

FIG. 5A is a side view illustrating the buffer used for the laminating device;

FIG. 5B is a side view illustrating the buffer used for the laminating device;

FIG. 5C is a side view illustrating the buffer used for the laminating device;

FIG. 5D is a side view illustrating the buffer used for the laminating device;

FIG. 5E is a side view illustrating the buffer used for the laminating device;

FIG. 5F is a side view illustrating the buffer used for the laminating device;

FIG. 6 is a plan view illustrating a plurality of buffers used for the laminating device; and

FIG. 7 is an explanatory view showing a problem of laminate-molding by a laminating device according to related art.

### DESCRIPTION OF EMBODIMENTS

### <Description of Configuration of Laminate Molding System and Laminating Device>

A laminate molding system 1 according to a first embodiment of the present invention will be described with reference to FIG. 1 in which a vacuum laminating device 2 and a press device 3 are shown in a cross-sectional view. In the laminate molding system 1, the press device 3 is disposed in a post-process of the vacuum laminating device 2. In the laminate molding system 1, an intermediate laminate A4 which has been conveyed from the vacuum laminating device 2 by carrier films F1 and F2 sent by a conveyance apparatus and which includes a substrate A1, which is a substrate layer having an uneven part, and a resin film A2, which is a resin layer, laminated to each other is pressure-molded by the press device 3.

A carrier film unwinding device 4 of a conveyance apparatus 10 serving as both as a transfer device for transferring the substrate A1, which is the substrate layer, and the resin film A2, which is the resin device, and a tension device includes a lower unwinding roll 411 and a driven roll 412. The orientation of the lower carrier film F1 unwound from the unwinding roll 411 is changed to a horizontal state in the driven roll 412. A placement stage 413 for placing the substrate A1, which is the substrate layer, and the resin film A2, which is the resin layer, both of the substrate A1 and the resin film A2 being sent in an overlapping manner from the pre-process, is provided at a part where the lower carrier film F1 is changed to the horizontal state. Further, the carrier film unwinding device 4 forming the conveyance apparatus 10 includes an upper unwinding roll 414 and a driven roll 415, and the upper carrier film F2 unwound from the unwinding roll 414 is overlaid on a laminate A3 formed of the substrate A1 and the resin film A2 in the driven roll 415. The substrate A1 and the resin film A2 are transferred by being sandwiched between the carrier films F1 and F2. Then, when laminate molding is performed in the vacuum laminating device 2, which is the laminating device, or the press device 3 through the carrier films F1 and F2, the laminated film A2 is prevented from melting and adhering to a device part. In the press device 3, in particular, the use of the carrier films F1 and F2 also has an advantage in that a certain buffer action is imparted when the intermediate laminate A4 is pressurized. Further, depending on the type of a laminate molded article A5, the laminate molded article A5 is peeled off from the carrier films F1 and F2 after the temperature of the laminate molded article A5 removed from the press device 3 is lowered, whereby the peeling or releasing can be performed in a good condition.

The vacuum laminating device 2 disposed in the post-process of the carrier film unwinding device 4 forming the conveyance apparatus 10 pressurizes the laminate A3 formed of the substrate A1 and the resin film A2 by a pressurizing body such as a diaphragm 211, which is an elastic film body, in a chamber Ch in a vacuum state (pressure reduced state) and laminate-molds the intermediate laminate A4, which is a primary molded article. The vacuum laminating device 2 is provided in such a way that a lower board 213 can be raised and lowered with respect to a fixedly-provided upper board 212 by a rising/lowering mechanism 214, and the chamber Ch can be formed inside when the lower board 213 is raised, and comes into contact with the upper board 212. The chamber Ch is connected to a vacuum pump that is not shown and is pressure reduceable. Further, a heat plate 215 is attached to the lower surface at the center of the upper board 212, and a heat-resistant elastic sheet 216 such as a rubber film (not shown) is attached to the surface of the heat plate 215 in such a way that it is bonded to a metal plate 218 or is directly attached thereto.

On the other hand, another heat plate 217 is attached to the upper surface at the center of the lower board 213. Further, the diaphragm 211, which is the elastic sheet formed of a heat-resistant rubber film such as a silicone rubber or a fluororubber, is attached to a part of the lower board 213 in the vicinity of the heat plate 217 in such a way that the diaphragm 211 covers the upper surface of the heat plate 217. Then, a pressurizing air is sent to a rear surface side of the diaphragm 211 by a compressor (not shown), whereby the diaphragm 211 expands in the chamber Ch and pressurizes the substrate A1 and the resin film A2 between the diaphragm 211 and the heat plate 217. Note that the diaphragm 211, which is an elastic sheet of the vacuum laminating device 2, may be attached to the upper board.

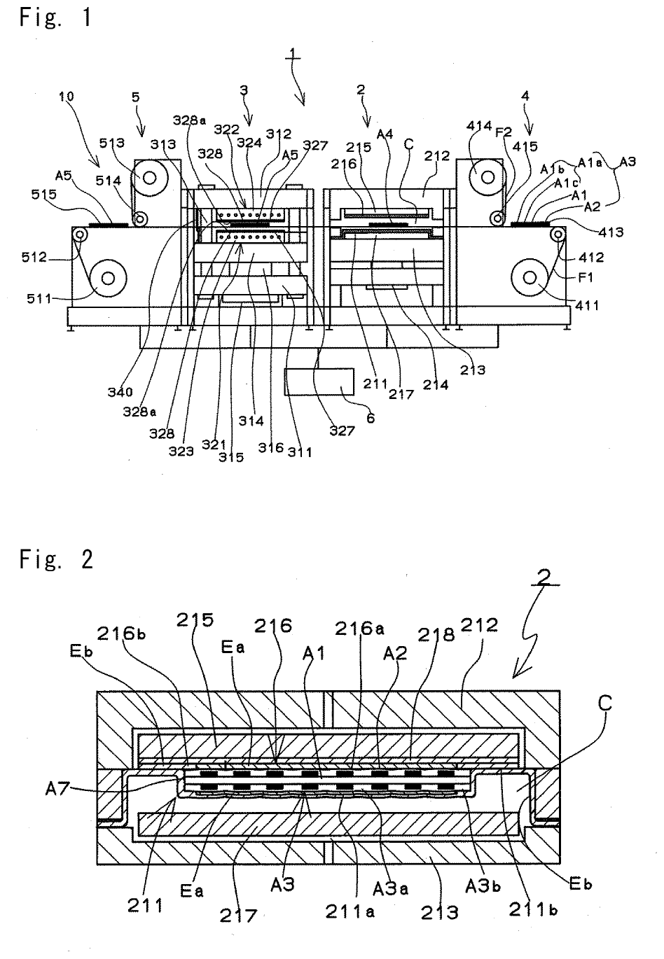

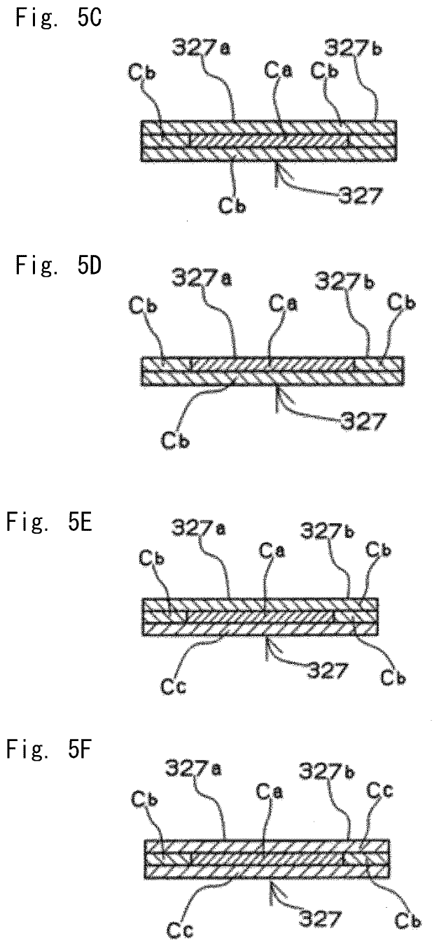

As shown in FIG. 2, in the diaphragm 211, which is an elastic sheet forming a part of the pressurizing means of the vacuum laminating device 2 according to this embodiment, the hardness of a peripheral part 211b is smaller than the hardness of a central part 211a. In this example, as shown in FIG. 5B, a concave part is provided in the central part of a rubber material Ea that corresponds to the whole area of the diaphragm 211, and a rubber material Eb having a high hardness is bonded to the concave part. This configuration is intended to achieve an object of making an elastic action of a part of the diaphragm 211, which is the elastic sheet, that is opposed to at least an outer peripheral part A3b of the laminate A3 smaller than an elastic modulus of a part of the diaphragm 211 that is opposed to a central part A3a of the laminate A3. In the diaphragm 211, which is the elastic sheet, to achieve the aforementioned configuration, the rubber material Ea or Eb used in the peripheral part 211b may be different from the rubber material Ea or Eb used in the central part 211a. Even though the central part 211a and the peripheral part 211b are made of the same material, the formulation ratio or bubble ratio may be made different from each other so that these elastic bodies may be different from each other only in hardness and elastic modulus thereof.

Regarding the aforementioned the elastic sheet 216 on the side of the upper board, like the diaphragm 211, which is the elastic sheet, the hardness of the peripheral part 216b is smaller than the hardness of the central part 216a. In this example, the rubber material Eb having a small hardness (having a small elastic modulus) is used for the peripheral part 216b of the elastic sheet 216 and the rubber material Ea having a relatively large hardness (having a relatively small elastic modulus) is used for the central part 216a of the elastic sheet 216. Note that one of the whole surface of the diaphragm 211 or the whole surface of the elastic sheet 216 may be made of the same rubber material.

The press device 3 disposed in the series direction in the post-process of the vacuum laminating device 2 further pressurizes the intermediate laminate A4 which has been pressure-molded by the vacuum laminating device 2, the intermediate laminate A4 including the substrate A1, which is the substrate layer having an uneven part, and the resin film A2, which is the resin layer, and being in a state in which there is an uneven part on the side of the resin film A2, thereby performing pressure-molding to obtain an even flatter laminate molded article A5. The press device 3 includes a substantially rectangular base board 311 provided on the lower side, and tie bars 313 provided upright between vicinities of four corners of an upper board 312, which is a substantially rectangular fixed board located above the base board 311. In the press device 3, a lower board 314 which is a substantially rectangular movable board can be raised and lowered between the base board 311 and the upper board 312. A position sensor 340 for detecting the distance between these boards is attached between the upper board 312 and the lower board 314. Further, the position sensor 340 may be attached between a pressurizing member 322 on the side of the upper board and a pressurizing member 321 on the side of the lower board and detect the distance between the pressurizing member 321 and the pressurizing member 322. Note that the position sensor 340 is not essential in the present invention.

Further, one pressurizing cylinder 315, which is pressurizing means that is actuated by hydraulic pressure, is provided in the base board 311, and a ram 316 of the pressurizing cylinder 315 is fixed to the back surface of the lower board 314. The pressurizing cylinder may either be a single acting cylinder or a double acting cylinder. A pipeline that supplies hydraulic oil from a pump (not shown) is connected to a pressurized oil chamber (not shown) of the pressurizing cylinder 315, and a hydraulic sensor for measuring the hydraulic pressure of the hydraulic oil is provided in the pipeline. While the pump is not limited thereto, a pump that can control the number of rotations by a servomotor is used. Further, a servovalve for controlling the flow rate may be provided in the pipeline. The number of pressurizing means may be two or larger. Regardless of whether there is one pressurizing means or two or more pressurizing means, the pressurizing means does not impart different pressurizing forces to respective parts of a pressurizing surface 328a via the lower board 314 in terms of control.

Note that the pressurizing means of the press device 3 according to the first embodiment may be other systems including means for directly moving the lower board or the like by rotating a ball screw by using an electric motor such as a servomotor or means for moving the lower board or the like via a toggle device by using an electric motor such as a servomotor. Further, the press device 3 may be the one in which the upper board is lowered with respect to the lower board. Furthermore, while the press device 3 according to the first embodiment does not include a chamber capable of being in a vacuum state, it may include a chamber capable of being in a vacuum state and pressurization may be performed in the vacuum chamber. In this case, the press device 3 may be a stage where pressurization is first performed (in FIG. 1, the position of the vacuum laminating device 2) or may be the post-process of the vacuum laminating device 2.

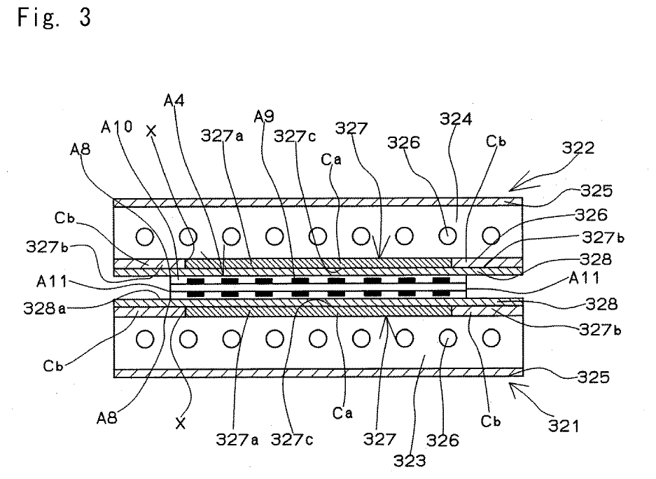

Since structures of the upper and lower pressurizing members 321 and 322 are substantially the same, the pressurizing member 321 of the lower board 314 will be described with reference to FIG. 3. The pressurizing member 321 includes a heat insulating material 325 that is provided between the lower board 314 and the pressurizing block body 323. Therefore, the pressurizing block body 323 of the press device 3 is attached to the lower board 314 via the heat insulating material 325 by using a bolt or the like that is not shown. The pressurizing block body 323, which is a block body having a predetermined thickness, includes a cartridge heater 326, which is heating means, inside thereof. Note that the heating means of the pressurizing member 321 may include, besides the cartridge heater 326, a rubber heater or the like that is provided on the surface or the like of the pressurizing block body 323. A buffer 327 is provided on the surface of the pressurizing block body 323 on the side of the intermediate laminate A4 and a metal plate 328, which is a plate-form member forming the pressurizing surface 328a, is provided on a surface 327c of the buffer 327 on the side of the intermediate laminate A4.

### <Description of Buffer of Press Device>

Next, the buffer 327 will be described. The buffer 327 has a sheet shape and the hardness of a peripheral part 327b is higher than the hardness of a central part 327a. This configuration is intended to achieve an object of making the buffer action of a part of the buffer 327 that is opposed to at least an outer peripheral end A8 of the laminate A4 smaller than the buffer action of a part of the buffer 327 that is opposed to a central part A9 of the laminate A4. In the buffer 327 to achieve the above object, a buffer material Ca or Cb used in the peripheral part 327b of the buffer 327 may be different from the buffer material Ca or Cb used in the central part 327a of the buffer 327. Even though the peripheral part 327b and the central part 327a are made of the same material, the formulation ratio or bubble ratio may be made different from each other so that the buffer 327 may include parts different from each other only in hardness thereof.

The buffer 327 may be made of, other than resin, an elastomer including rubber, fiber, paper, or composites thereof. As one example, but not limited thereto, the central part 327a may be made of fluororesin ((Rockwell R Scale (ISO 2039-2) 20 to 113) and the peripheral part 327b may be made of polyimide (Rockwell R Scale 110 to 130). Alternatively, the central part 327a may be made of an elastomer including rubber and the peripheral part 327b may be made of resin that has a hardness relatively higher than that of the central part 327a. Even when they are made of the same material, their hardness may be relatively different from each other due to the difference between additives or porosities.

When a resin film is used for the buffer 327 (buffer material) in the present invention, a thermosetting resin film, an engineering plastic film, or an industrial functional film is preferably used. The fluororesin film may be polytetrafluoroethylene (PTFE) also called Teflon (registered trademark) (Rockwell R Scale (ISO 2039-2) 20, load deflecting temperature (° C. (1.81 MPa)) 55° C., maximum temperature of use: 260° C.), PFA (Rockwell R Scale 50, load deflecting temperature 47° C., maximum temperature of use: 260° C.), FEP (Rockwell R Scale 50, load deflecting temperature 50° C., maximum temperature of use: 200° C.), PCTFE (Rockwell R Scale 80, load deflecting temperature 90° C., maximum temperature of use: 120° C.), ETFE (Rockwell R Scale 50, load deflecting temperature 74° C., maximum temperature of use: 150° C.), ECTFE (Rockwell R Scale 50, load deflecting temperature 77° C., maximum temperature of use: 150° C.), PVDF (Rockwell R Scale 93 to 116, load deflecting temperature 100° C., maximum temperature of use: 156° C.), and so on, and may be any one of the aforementioned fluororesin films. Amon them, PTFE is often used since it is easy to obtain and has a high maximum temperature of use. For polytetrafluoroethylene (PTFR), there are some with a low Rockwell R Scale value of about 18, and laminate-molding may be performed in the way similar to that described above even with a resin film with a hardness of about R15. The fluororesin used for the fluororesin film is not cross-linked, unlike fluororubber, and does not have elasticity, unlike fluororubber.

Further, examples of the thermosetting resin film other than the fluororesin (FR) film used for the buffer 327 in the present invention include, but not limited thereto, phenol resin (PF), urea resin (UF), melamine resin (MF), allyl resin (PDAP), alkyd resin (ALK), unsaturated polyester (UP), epoxy resin (EP), diallyl phthalate (DAP), polyurethane resin, silicone resin (SI), polyimide (PI) and so on. The thermosetting resin film is suitably selected since it has excellent heat resistance and is unlikely to be degraded even when the temperature used for the press device 3 for laminate molding is relatively high.

Further, the resin film used for the buffer 327 (buffer material) may be an engineering plastic. The engineering plastic in the present invention is defined to be a resin with heat resistance of 100° C. or higher, tensile strength of 49 MPa or higher, and bending elastic modulus of 2.4 GPa or higher. It is assumed that the engineering plastic according to the present invention includes general-purpose engineering plastic (abbreviated as general-purpose enpla) and super engineering plastic (abbreviated as special enpla). Examples of the general-purpose engineering plastic used for the buffer include, but not limited thereto, polyamide (PA), polyacetal (POM), polycarbonate (PC), modified polyphenylene ether (PPE), polybutylene terephthalate (PBT), glass fiber reinforced polyethylene terephthalate (GF-PET), and ultra high molecular weight polyethylene (UHPE). The general-purpose engineering plastic may be used when the laminate-mold press device is used at a relatively low temperature.

Further, the super engineering plastic is a resin with heat resistance of 150° C. or higher, and examples of the general-purpose engineering plastic used for the buffer may include, but not limited thereto, polysulfone (PSF), polyethersulfone (PES), polyphenylene sulfide (PPS), liquid crystal polymer (LCP), polyethylene naphthalate (polyether nitrile) (PEN), polyarylate (PAR), polyethersulfone (PES), polyarylate (PAR), polyetheretherketone (PEEK), polyetherimide (PFI), polyamideimide (PAI), polyaminobismaleimide (PABM), polybismaleimide triazine resin (BT-resin), polyoxybenzoyl (POB), aramid (polyamide consisting only of an aromatic backbone, and sometimes referred to as Ar), and thermoplastic polyimide (PI).

Of the engineering films including the above super engineering plastic, polyimide (both thermoplastic and thermosetting) (load deflecting temperature at least 260° C., Rockwell R Scale 110 to 130), polyether ketone (load deflecting temperature 140° C., Rockwell R Scale 126), polysulfone (load deflecting temperature, Rockwell R Scale 110 to 120), polyphenylene sulfide (load deflecting temperature 260° C., Rockwell R Scale 100), polyethersulfone (load deflecting temperature 203° C., Rockwell R Scale 100), polyethylene naphthalate (polyether nitrile film) (load deflecting temperature 330° C., Rockwell R Scale 114), aramid (load deflecting temperature 200° C. to 230° C.) may be resins that are particularly suitable in the present invention, and they are also relatively easy to obtain commercially. Further, at least one of the above resins may be used as the resin that is particularly suitable in the present invention. Of the aforementioned ones, a polyimide film or a resin film having polyimide as a main component is preferably used. The polyimide film is relatively easy to obtain and has excellent heat resistance.

Further, when the buffer 327 (buffer material) is an elastomer including rubber, silicone rubber, fluororubber or the like having an excellent heat resistance is selected. When these rubbers are selected, the Shore A hardness is preferably, but not limited thereto, 30 degrees or higher. Alternatively, when the buffer 327 is measured in Shore A hardness, the difference between the Shore A hardness of the buffer material Cb of the peripheral part 327b and that of the buffer material Ca of the central part 327a is preferably at least 5 degrees.

The thickness of the buffer 327 is preferably from 0.01 mm to 2.00 mm, and further preferably from 0.02 mm to 1.00 mm. In this embodiment, the thickness of the central part 327a of the buffer 327 is the same as that of the peripheral part 327b of the buffer 327. However, this does not mean that they should not have thicknesses different from each other. As one example, their thicknesses may differ from each other in a range of 1.00 mm or smaller. When, for example, the hardness of the part of the buffer 327 corresponding to the outer peripheral end A8 of the intermediate laminate A4 is higher than the hardness of the central part 327a, the thickness of the part of the buffer 327 corresponding to the outer peripheral end A8 may be reduced. Further, when the hardness of the central part 327a is the same as the hardness of the part of the buffer 327 corresponding to the outer peripheral end A8 or the hardness of the part of the buffer 327 corresponding to the outer peripheral end A8 is lower than the hardness of the central part 327a, the thickness of the outer peripheral end A8 may be much larger than the thickness of the central part 327a. That is, it is sufficient, in the buffer 327 according to the present invention, that a physical property for reducing deformation of the metal plate 328 which is a plate-form member in at least a part of the buffer 327 opposed to the outer peripheral end A8 of the intermediate laminate A4 or the like, which is the laminate, be larger than a physical property for reducing deformation of the metal plate 328 which is the plate-form member in the part of the buffer 327 that is opposed to the central part A9 of the intermediate laminate A4 when the pressure is applied. That is, it is sufficient that the deformation of the metal plate 328 when it comes into contact with the peripheral part 327b of the buffer 327 be reduced when the pressure is applied.

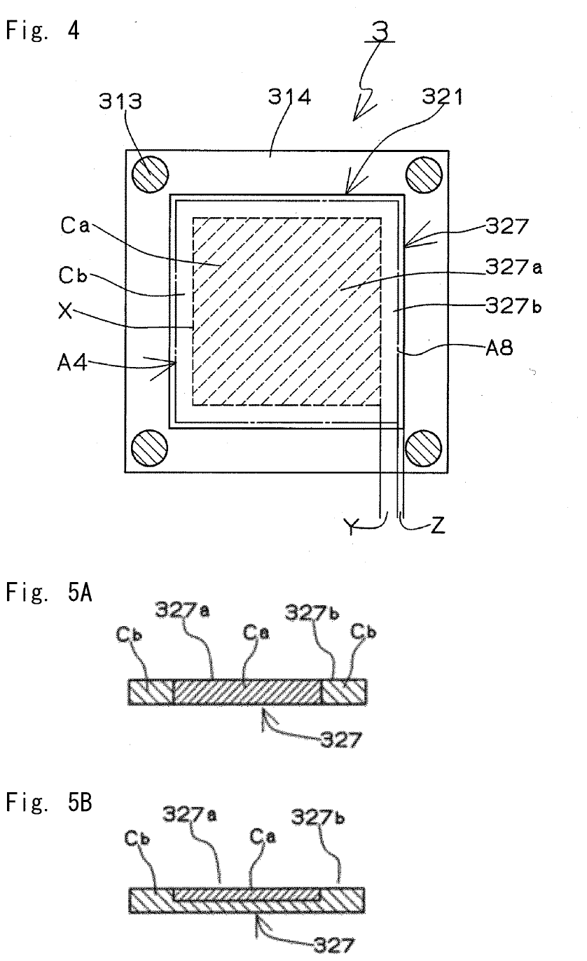

Further, as shown in the explanatory view of FIG. 4 in which the metal plate 328 is omitted, a boundary X between the resin material (or the rubber material) which is the buffer material Cb of the buffer 327 having a high hardness and the resin member (or the rubber material Ca) which is the buffer material Ca of the buffer 327 having a low hardness is preferably provided in 30 mm in the inner direction Y relative to the outer peripheral end A8 and 10 mm in the outer direction Z relative to the outer peripheral end A8 in the position where the intermediate laminate A4 is molded. Therefore, the boundary X may be formed on the pressurizing surface 328a of the intermediate laminate A4 or may be formed in a part other than the pressurizing surface 328a. The above boundary X varies depending on the type and the size of the laminate including the intermediate laminate A4.

On the surface 327c of the buffer 327 on the side of the intermediate laminate A4, the metal plate 328, which forms the pressurizing surface 328a and is a plate-shaped body made of a hard material is overlapped. While the material of the metal plate 328 is stainless steel, other metals such as iron or aluminum, or ceramics may instead be used. The planar shape of the metal plate 328 is substantially the same as the planar shape of the pressurizing block body 323. The metal plate 328 has a thickness of about 0.05 mm to 5.0 mm. The surface of the metal plate 328, which is a pressurizing surface 328a, is mirror-finished. Further, the pressurizing surface 328a, which is a surface of the metal plate 328, is subjected to surface treatment such as nitriding treatment. Fixing and attachment of the members such as the pressurizing block body 323, the buffer 327, the metal plate 328 forming the pressurizing surface 328a and the like are performed by an appropriate method such as bolts, clamps, heat welding, or adhesive. In FIG. 3, the length of each of the pressurizing block body 323 forming the pressurizing member 321, the buffer 327, the metal plate 328 forming the pressurizing surface 328a and the like in the thickness direction with respect to the length thereof in the horizontal direction is drawn much larger than it actually is.

### <Further Description of Configuration of Laminate Molding System>

In the press device 3 according to the first embodiment, the upper board 312 has a pressurizing member 322 having the same side size, the same area, and the same structure as that of the lower board 314. That is, the upper board 312 also includes a pressurizing block body 324, a metal plate 328, a buffer 327 having a configuration similar to that in FIG. 3 and the like.

Note that, in the present invention, it is sufficient that at least one of the lower board 314 or the upper board 312 be provided with the buffer 327 between the plate-form member forming the pressurizing surface 328a and the pressurizing block body and the hardness of the peripheral part 327b of this buffer 327 be higher than the hardness of the central part 327a of this buffer 327. When, for example, the resin film A2 is laminated only on one surface of the substrate A1, the object may be achieved if the buffer 327 of only the board that is opposed to the resin film A2 is formed in such a way that the hardness of the peripheral part 327b of this buffer 327 is higher than the hardness of the central part 327a of this buffer 327.

In the post-process of the press device 3, a carrier film winding device 5 forming the conveyance apparatus 10 that serves as both a transfer device and a tension device of the laminate molded article A5 is provided. The carrier film winding device 5 includes a lower winding roll 511 and a driven roll 512, and a lower carrier film F1 is wound by the winding roll 511. Further, the carrier film winding device 5 includes an upper winding roll 513 and a driven roll 514, an upper carrier film F2 is peeled off from the laminate molded article A5 at the part of the driven roll 514, and the upper carrier film F2 is wound around the upper winding roll 513. A take-out stage 515 of the laminate molded article A5 is provided at a part where only the lower carrier film F1 is fed in the horizontal state.

The control of the amount of feeding of each of the upper and lower carrier films F1 and F2 may be performed by detecting diameters of the films wound by the winding rolls 511 and 513 by measurement and controlling the numbers of rotations (rotation angles) of the winding rolls 511 and 513 by a servomotor. Further, a rotation number detection device such as a rotary encoder may be provided in the driven roll 512. Further, as the transfer device of the carrier films F1 and F2, a transfer device that grips both sides of the carrier films F1 and F2 and pulls the carrier films F1 and F2 toward the post-process may be provided.

Next, a control device 6 of the laminate molding system 1 will be described. The control device 6 is connected to the vacuum laminating device 2, the press device 3, the carrier film unwinding device 4, and the carrier film winding device 5. In relation to the press device 3, in particular, the control device 6 controls the temperature of the heating means and the pressurizing force.

### <Description of Lamination Method>

Next, a lamination method of the substrate A1, which is the substrate layer, and the resin film A2, which is the resin layer, using the laminate molding system 1 according to the first embodiment will be described. In the laminate molding system 1 at the time of continuous molding, pressure-molding is concurrently performed in a batch-processing manner by sequence control in the press device 3, which is a laminating device just like the diaphragm-type vacuum laminating device 2. However, here, the description will be given along a molding order of a to-be-laminated material for one molding cycle, namely the substrate A1 and the resin film A2 (laminated film).

The substrate A1 placed on the placement stage 413 of the conveyance apparatus 10 is a circuit board for build-up having an uneven part A1a including a convex part A1b having a copper foil adhered to a substrate surface and a concave part A1c not having a copper foil. The thickness of the copper foil (height with respect to the substrate part) is, for example, but not limited thereto, about several μm to several tens μm, and is 0.1 mm or less in most cases. The resin film A2 is overlapped on each of upper and lower surfaces of the substrate A1 to form a laminate A3 for build-up molding. While only one laminate A3 is shown in FIG. 1, a plurality of laminates A3 may be laminate-molded at the same time.

The resin film A2 according to the first embodiment is an insulating film, which is used after PET films laminated on both respective surfaces thereof are peeled off from the original storage state. The resin material of the resin film A2 is a thermosetting resin such as epoxy or a resin containing a thermosetting resin as a main material. Further, as materials other than the thermosetting resin, a thermoplastic resin, or various materials and additives are contained for the purpose of adjusting roughness, imparting flame retardancy, imparting low expansion, imparting fluidity, imparting film formability, low dielectric loss tangent (imparting insulating property), and lowering a water content. The film to be laminated may be, besides the insulating film, a photosensitive film or the like. The component of the film to be laminated may be, but not limited to, only a thermoplastic resin or only a thermosetting resin.

Then, the laminate A3 placed on the placement stage 413 is moved together with the upper and lower carrier films F1 and F2 with the rotational driving of the winding rolls 511 and 513, and is fed into and positioned in the chamber Ch of the vacuum laminating device 2 which is in the open state. At this time, as shown in FIG. 3, it is required that the peripheral part 211b of the diaphragm 211 in the vacuum laminating device 2 having a low hardness is stopped in such a manner that it is opposed to the outer edge of the laminate A3 formed of the substrate A1 and the resin film A2 sandwiched between the carrier films F1 and F2. In order to achieve this positioning, it is required to accurately perform control of the amount of feeding of the intermediate laminate A4 by the upper and lower carrier films F1 and F2 and control for stopping the laminate A3 in the press position of the press device 3 by using a servomotor or the like. A monitoring device such as a camera that monitors whether the laminate A3 is stopped in the press position may be attached as needed.

Next, in the vacuum laminating device 2, the chamber Ch is closed to form the chamber Ch in a vacuum state by a vacuum pump (not shown). When the chamber Ch is in a vacuum state, a pressurizing air is sent to the rear surface side of the diaphragm 211 to make the diaphragm 211 to expand into the chamber Ch, thereby pressuring the laminate A3 formed of the substrate A1 and the resin film A2 between the diaphragm 211 and the elastic sheet 216 of the heat plate 215 on the side of the upper board 212.

At this time, since the hardness of the peripheral part 211b of the diaphragm 211 is low, mainly this peripheral part 211b of the diaphragm 211 is extended and expands. Then, the central part 211a first comes into contact with the substrate A1 and the like, and the peripheral part 211b then comes into contact with the substrate A1 and the like shortly after the central part 211a does. The pressurizing force (surface pressure) that is applied to the substrate A1 and the like by the diaphragm 211 is, as one example, 0.01 MPa to 2.5 MPa, and particularly preferably 0.3 MPa to 1.0 MPa. Then, the substrate A1 and the resin film A2 are bonded to each other in such a manner that the laminated film A2 is buried in the concave part A1c of the substrate A1, whereby the intermediate laminate A4, which is the primary molded article, is laminate-molded.

Further, as described above, as shown in FIG. 2, in the diaphragm 211, the hardness of the peripheral part 211b is smaller than the hardness of the central part 211a. Therefore, when the substrate A1 and the resin film A2 are pressurized and laminated to each other, the force applied to the end A6 of the substrate A1 and the resin film A2 and the vicinity of the end is slightly lower than the force applied in the central part 211a. Further, since the hardness of the peripheral part 211b of the diaphragm 211 is low and thus the peripheral part 211b of the diaphragm 211 has a high shape-following property, the force applied by the diaphragm 211 which comes into contact with the side surface A7 of the end A6 of the substrate A1 and the resin film A2 from the side surface A7 becomes relatively large. Therefore, in the vacuum laminating device 2 according to this embodiment, it is possible to prevent a problem that the resin layer flows outside from the side surface A7 when the pressure is applied.

However, there is still unevenness on the surface of the resin film A2 of the intermediate laminate A4 laminate-molded by the vacuum laminating device 2 in accordance with the shape of the uneven part A1a of the substrate A1. Further, at this time, if the content of inorganic materials in the resin film A2 to be used is high, the fluidity of the molten or softened resin is low, whereby it is likely that more uneven parts will remain even more.

When the intermediate laminate A4 obtained by bonding the substrate A1 having the uneven part A1a and the resin film A2 is laminate-molded in the vacuum laminating device 2, the chamber Ch is opened. Then, by feeding the next carrier films F1 and F2 by the carrier film unwinding device 4 and the carrier film winding device 5 which correspond to the conveyance apparatus 10, the intermediate laminate A4 is conveyed between the upper board 312 and the lower board 314 of the press device 3 and is stopped at a predetermined pressurize position. At this time as well, accurate feeding control of the upper and lower carrier films F1 and F2 is performed by a servomotor or the like by the same pitch as that when the laminate A3 is delivered to the vacuum laminating device 2. Further, a monitoring device such as a camera that monitors whether the intermediate laminate A4 is stopped in the press position may be attached to the side of the press device 3.

After the intermediate laminate A4 is stopped at a predetermined position of the press device 3 to further smooth the intermediate laminate A4, the pressurizing cylinder 315 of the press device 3 is actuated and the pressurizing process is started. In the pressurizing process, the lower board 314 and the pressurizing block body 323 and the like of the pressurizing member 321 are raised, the metal plate 328 attached to the pressurizing block body 323 via the buffer 327 comes into contact with the intermediate laminate A4 through the lower carrier film F1, which further pushes the intermediate laminate A4 upward, and the upper surface of the intermediate laminate A4 comes into contact with the metal plate 328 on the side of the upper board via the upper carrier film F2, and thereafter the pressurization control is started.

In this embodiment, pressurization control of the press device 3 is performed by pressure control and a surface pressure of, as an example, 0.01 MPa to 2.5 MPa, and further preferably from 0.5 MPa to 1.5 MPa is applied to the intermediate laminate A4. However, the pressure control may be the one in which the pressure is changed in the middle of the process. Further, pressure control may be performed in the first half of the pressurizing process of the press device 3 and position control (or speed control) may be performed in the second half of the pressurizing process. This does not exclude a case in which position control (or speed control) is performed for the entire process from the start to the end.

When the pressurizing process is performed by the press device 3, in the case where the whole surface of the buffer 327 is constant, like in related art, as shown in FIG. 7, there is a problem that, when the intermediate laminate A4 including the substrate layer and the resin layer is pressurized, stress concentrates in the outer peripheral end A8 of the intermediate laminate A4 and the resin in the vicinity of the end flows outside from the side surface A10 of the intermediate laminate A4. However, in the present invention, as shown in FIG. 3, the buffer 327 is provided between the pressurizing block body 323 and the metal plate 328 and the hardness of the peripheral part 327b of the buffer 327 is higher than the hardness of the central part 327a of the buffer 327. (The hardness of the central part 327a is less than the hardness of the peripheral part 327b). Therefore, when the intermediate laminate A4 is pressurized, the part including the outer peripheral end A8 of the intermediate laminate A4 is pressed via the metal plate 328 in the peripheral part 327b of the buffer 327 in which the buffer action is small, and the central part A9 of the intermediate laminate A4 is pressed via the metal plate 328 in the central part 327a of the buffer 327 in which the buffer action is large.

As a result, there is no flexure in the peripheral part of the metal plate 328 as shown in FIG. 7, and no stress concentration in the outer peripheral end A8 of the intermediate laminate A4 via the buffer 327 and the metal plate 328. As a result, the metal plate 328 is maintained to be substantially flat. Therefore, it is possible to prevent the resin in the vicinity of the outer peripheral end A8 of the intermediate laminate A4 from flowing out from the side surface A10 of the intermediate laminate A4.

When the predetermined press process time ends, the press device 3 is opened and the laminate molded article A5 is sent to the take-out stage by feeding of the upper carrier film and the lower carrier film.

Then, the laminate molded article A5 is taken out on the take-out stage.

### Description of Other Embodiments

Next, a laminating device of a laminate molding system 1 according to other embodiments will be described. The laminate molding device according to the present invention may be the one in which only a single vacuum laminating device 2 including a diaphragm 211 shown in FIG. 1 is provided. Further, the laminate molding device according to the present invention may be the one in which one or a plurality of press devices of the present invention is disposed in a post-process of the press device 3 of the laminate molding system 1 according to the first embodiment. Alternatively, the press device provided in the post-process is disposed between a pressurizing block body and a metal plate-form member, which is a pressurizing surface. The buffer may be made of a uniform material.

Alternatively, the laminate molding system 1 may be the one in which the vacuum laminating device 2 including the diaphragm 211 shown in FIG. 1 is not disposed and the press device 3 serves as a pressurizing device in the first pressurizing process. In this case, the press device 3 includes a vacuum chamber and constitutes a vacuum laminating device. The vacuum laminating device formed of the press device 3 itself forms a line of the laminate molding system. Further, the laminate molding system 1 may include one or a plurality of press devices in the post-process of the press device 3 (regardless of whether it includes a vacuum chamber) of the present invention, and each of the press devices may be a press device which is the same as the press device 3 or a press device including a thin metal plate forming a pressurizing surface on the surface of the pressurizing block body via a buffer.

### <Description of Variations of Combinations and Shapes of Elastic Sheets>

Next, with reference to FIGS. 5A-5F, some variations in which the hardness of the peripheral part 327b of the buffer 327 and the hardness of central part 327a of the buffer 327 in the present invention are made different from each other will be described. As shown in FIG. 5A, the buffer 327 (buffer sheet) may be made of two kinds of buffer materials Ca and Cb and the peripheral part 327b and the central part 327a, which are formed of the different respective buffer materials Ca and Cb, may be formed without overlapping each other. Further, as shown in FIG. 5B, the buffer 327 may be formed of two kinds of buffer materials Ca and Cb, and the buffer material Ca having a low hardness may be disposed in a central concave part Cb1 of the buffer material Cb which is provided on the whole surface and has a relatively high hardness. Alternatively, as shown in FIG. 5C, the buffer 327 may be formed of two kinds of buffer materials Ca and Cb, and the buffer material Ca having a low hardness may be held in a central part which is between the buffer materials Cb having a high hardness on both surfaces. In this case, in a peripheral part between the buffer materials Cb having a low hardness on the both surfaces, a buffer material Cb having a high hardness and whose type is the same as that of the buffer material Cb on the both surfaces is disposed. Further, as shown in FIG. 5D, a buffer material Cb having a relatively high hardness may cover the whole surface of one surface side, the buffer material Ca having a hardness lower than that of the buffer material Cb may be disposed in the central part 327a, and the buffer material Cb which is the same as the buffer material Cb that covers the whole surface may be disposed in the peripheral part 327b.

Further, the buffer 327 may be made of three or more buffer materials. As one example, as shown in FIG. 5E, the hardness of the buffer material Cb and the hardness of the buffer material Cc that are provided on both surface sides may be different from each other, the peripheral part 327b of the buffer that is sandwiched therebetween may be made of the same material as that of the buffer material Cb or Cc, which is one of the above surfaces, and the central part 327a may be made of a material that is different from the buffer materials Cb and Cc of both surfaces and has a hardness relatively lower than those of the buffer materials Cb and Cc of the peripheral part. Further, as shown in FIG. 5F, the buffer materials on the both surface sides may be the same buffer material Cc, and each of the buffer material Cb of the peripheral part 327b of the buffer material sandwiched therebetween and the buffer material Ca of the central part 327a of the buffer material sandwiched therebetween may be different from the buffer material Cc of the both surfaces, and the buffer material Cb of the peripheral part 327b may have a hardness relatively higher than that of the buffer material Ca of the central part 327a.

In each of FIGS. 5A to 5F, the upper side of the buffer 327 may come into contact with the metal plate 328 (in each of FIGS. 5A to 5F, the lower side of the buffer 327 may come into contact with the pressurizing block body 323), or the upper side of the buffer 327 may come into contact with the pressurizing block body 323 in each of FIGS. 5A to 5F (the lower side of the buffer 327 may come into contact with the metal plate 328). By making the hardness of the whole surface of the buffer 327 which comes into contact with the metal plate 328 uniform and changing the hardness of the opposite rear surface side which comes into contact with, for example, the pressurizing block body 323 or of the central buffer 327 in such a way that the central part 327a of the buffer 327 has a hardness relatively lower than that of the peripheral part 327b of the buffer 327, a shape change associated with a distinct difference between hardnesses may not appear on a surface of a laminate such as the intermediate laminate A4. Further, the buffer materials Ca, Cb, Cc and the like of the buffer 327 are preferably bonded by a heat-resistant adhesive. Alternatively, the buffer materials Ca, Cb, Cc and the like of the buffer 327 are preferably engaged by thermofusion or bolts.

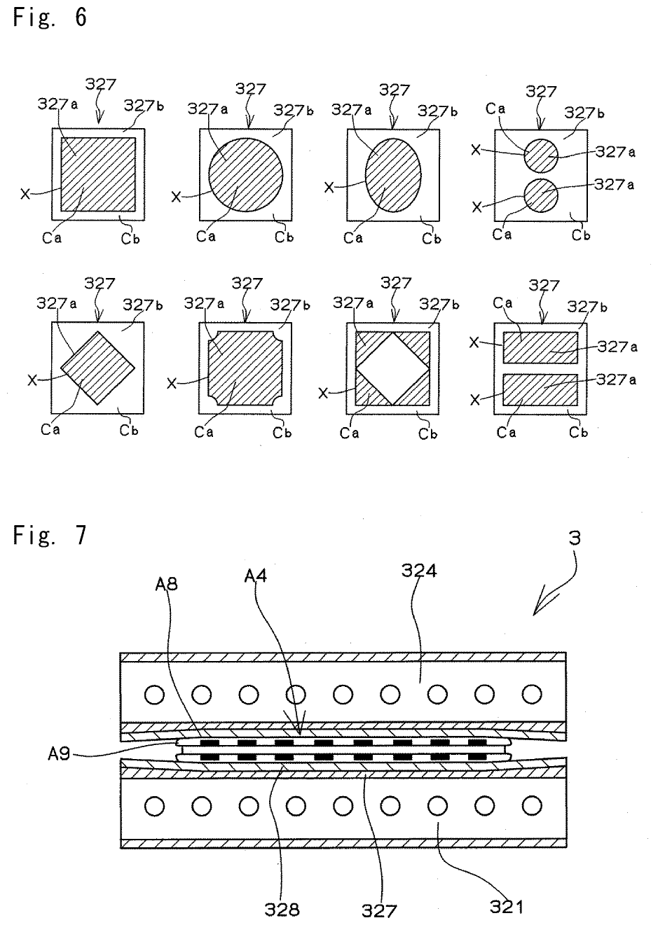

Further, an arrangement relation in which the peripheral part 327b and the central part 327a of the buffer 327 are seen in a plan view may be changed as shown in FIG. 6 according to the shapes or the number of laminates. That is, the shape of the central part 327a of the buffer 327 having a low hardness is not limited to rectangular (including a square and a rectangle) and may be circular, oval, diamond, or a shape with four chamfered corners. Further, in accordance with the number of laminates, a plurality of relatively low-hardness parts of the buffer 327 may be provided. Therefore, “the buffer action in the part of the buffer that is opposed to at least the outer peripheral part of the laminate is smaller than the buffer action in the part of the buffer that is opposed to the central part of the laminate” in the present invention includes a structure in which two or more parts of the buffer 327 having a hardness lower than that in the other part of the buffer 327 (the two or more parts being parts of the buffer 327 where the buffer action is large) are provided in the buffer 327 in accordance with the number of laminates. While the central part 327a having a low hardness is hatched and the boundary X is shown by the solid line in FIG. 6, the whole surface side (metal plate side) may be one uniform buffer 327 and the hardness of the central part 327a on the central side or the rear surface side may be relatively lower than that of the peripheral part 327b.

The configuration of the buffer 327 described above is intended to reduce the resin flow from the laminate using mainly the difference between physical effects such as the difference between the hardness of the peripheral part 327b and the hardness of the central part 327a. Instead, the resin flow from the laminate may be reduced by using a difference between thermal effects of the buffer 327. Specifically, heat conductivity, which is one of heat transfer properties of at least a part of the buffer 327 that is opposed to the outer peripheral end A8 of the laminate such as the intermediate laminate A4 is made smaller than the heat conductivity, which is one of heat transfer properties of a part of the laminate that is opposed to the central part A9. Accordingly, in the metal plate 328 that is provided on the side of the surface 327c of the buffer 327, the temperature of the central part 327a becomes high and the temperature of the peripheral part 327b becomes low. As a result, the resin flow in the vicinity of the outer peripheral end A8 of the intermediate laminate A4 that comes into contact with the metal plate 328 of the peripheral part is reduced. Note that the buffer material used in the peripheral part 327b of the buffer 327 and the buffer material used in the central part 327a of the buffer 327 may have the same heat conductivity, and the difference between heat transfer properties may be caused by the difference between porosities or the difference between other mixed substances.

Although the present invention is not listed one by one, the present invention is not limited to those of the first embodiment and it goes without saying that the present invention is also applied to those modified based on the gist of the present invention by those skilled in the art and those obtained by multiplying the respective descriptions. The laminated molded article A5 laminate-molded in the laminate molding system 1 may be, other than a build-up substrate, another circuit board, a semiconductor wafer, or the like without any limitation. Further, the substrate layer is not limited to the substrate.

This application is based upon and claims the benefit of priority from Japanese Patent Application No. 2021-211343, filed on Dec. 24, 2021, the disclosure of which is incorporated herein in its entirety by reference.

### REFERENCE SIGNS LIST

1 LAMINATE MOLDING SYSTEM
2 VACUUM LAMINATING DEVICE
3 PRESS DEVICE
212, 312 UPPER BOARD
213, 314 LOWER BOARD
321, 322 PRESSURIZING MEMBER
323, 324 PRESSURIZING BLOCK BODY
327 BUFFER
327A CENTRAL PART
327B PERIPHERAL PART
328 METAL PLATE
Ca, Cb, Cc BUFFER MATERIAL

1. A laminating device configured to pressurize a laminate including a substrate layer and a resin layer between opposing boards of a press device at a predetermined temperature, wherein
at least one of the boards includes a buffer between a plate-form member forming a pressurizing surface and a pressurizing block body.

2. The laminating device according to claim 1, wherein
a physical property for reducing deformation of the plate-form member in at least a part of the buffer that is opposed to an outer peripheral end of the laminate when the pressure is applied is larger than a physical property for reducing deformation of the plate-form member in a part of the buffer that is opposed to a central part of the laminate.

3. The laminating device according to claim 1, wherein
a buffer action in at least a part of the buffer that is opposed to an outer peripheral end of the laminate is smaller than a buffer action in a part of the buffer that is opposed to a central part of the laminate.

4. The laminating device according to claim 1, wherein
a heat transfer property of at least a part of the buffer that is opposed to an outer peripheral end of the laminate is smaller than a heat transfer property of a part of the buffer that is opposed to a central part of the laminate.

5. A lamination method for pressurizing a laminate including a substrate layer and a resin layer between opposing boards of a press device at a predetermined temperature, wherein
at least one of the boards includes a buffer between a plate-form member forming a pressurizing surface and a pressurizing block body, and
the lamination method comprises pressing a part of the laminate including an outer peripheral end of the laminate via the plate-form member in a part of the buffer where a buffer action is small and pressing a central part of the laminate via the plate-form member in a part of the buffer where a buffer action is large.

6. The lamination method according to claim 5, wherein the laminate is a build-up substrate.

7. The laminating device according to claim 1, wherein a hardness of a peripheral part of the buffer is higher than that of a central part of the buffer.
